(19) United States
(12) Patent Application Publication
(10) Pub. No.: US 2026/0300061 A1
(43) Pub. Date: Oct. 1, 2026

(54) METHOD AND DEVICE FOR ANOMALY EVENT DETECTION

(71) Applicant: EATON INTELLIGENT POWER LIMITED, Dublin 4 (IE)

(72) Inventors: Xiangying MENG, Troy, MI (US); Souvik CHANDRA, Littleton, CO (US); Robert OWUSUMIREKU, Milwaukee, WI (US); Michael NOWAK, Milwaukee, WI (US); Dmitry ISHCHENKO, Cary, NC (US)

(21) Appl. No.: 19/477,845

(22) PCT Filed: May 17, 2024
(86) PCT No.: PCT/EP2024/063756

§ 371 Date: Oct. 23, 2025

Related U.S. Application Data
(60) Provisional application No. 63/503,170, filed on May 19, 2023.
(60) Provisional application No. 63/503,171, filed on May 19, 2023.

(51) Int. Cl. G06F 11/00

(52) U.S. Cl. CPC G06F 11/006; G06F 2201/81

(57) ABSTRACT

Some embodiments are directed to a method for anomaly event detection in an electrical or electromechanical system. The method is carried out by a device including a processor, and includes acquiring time series data points representative of a variable of the system; determining whether a difference (Δ(k)) between a data point (X(k)) and a moving average of data points is greater than a first threshold. The first threshold can be a function of a mean of said difference; as a result of the determination. The method can include providing an input to a leaky integrator configured to count data points for which the difference is greater than the first threshold; determining whether an output of said integrator is greater than a second threshold and in the affirmative, generating a signal indicative of the detection of an anomaly event.

### TECHNICAL FIELD

The field of the disclosure relates generally to a method and a device for detecting events in electrical or electromechanical systems such as, but not limited to, utility power systems.

### BACKGROUND ART

Electrical or electromechanical systems, for example utility power systems, can be monitored for the occurrence of potentially abnormal changes within the system, using appropriate monitoring devices. Monitoring may be performed based on changes in system characteristics. Events may signal a degradation, a fault, a cyber-intrusion, or an impending failure, possibly with catastrophic consequences. Such events require fast detection methods to be addressed rapidly. Due to the possibly limited computational resources of monitoring devices, an event detection method may thus need to be designed with limited processing capabilities in mind. Moreover, there is a need to distinguish between anomaly event signatures and noise added to the baseline operation data to reduce the number of false alarms.

### SUMMARY OF THE INVENTION

A first aspect concerns a method for anomaly event detection in an electrical or electromechanical system, said method being carried out by a device comprising a processor, said method comprising:
acquiring time series data points representative of a variable of the system;
determining whether a difference between a data point and a moving average of data points is greater than a first threshold, wherein the first threshold is function of a mean of said difference;
as a result of the determination, providing an input to a leaky integrator configured to count data points for which the difference is greater than the first threshold;
determining whether an output of said integrator is greater than a second threshold and in the affirmative, generating a signal indicative of the detection of an anomaly event.

The time series data points may be derived from data obtained from a sensor.

The claimed method extracts an anomaly event from a noisy signal. The distinction is based on the assumption that an anomaly event is characterized by the fact that it induces relatively long-lasting changes in the system, compared to noise. The changes are tracked based on an adaptive threshold compared to a moving average used as baseline reference and through the use of a leaky integrator which allows reducing the impact of isolated out of boundary data values due to noise or other distortions on the change tracking. This allows limiting false alarms while still enabling detection of subtle changes that persist over a relatively long time.

An anomaly event comprises normal system operation events and abnormal events. Examples of normal events, e.g. in a power line system are transformer inrush and cap bank switching. An example of an abnormal event is a high impedance fault event. Both normal events and abnormal events are distinctly different from normal baseline operation. Once an anomaly event has been detected, further processing may be applied to distinguish between normal system operation events and abnormal events.

According to one or more embodiments, wherein time series data representative of a variable of the system comprises one among one or more measured currents, voltages or powers, or a variable representative of harmonics of one or more measured currents, voltages or powers. E.g. several currents, voltages, powers may be measured and summed for use in the method, either directly or after additional processing.

According to one or more embodiments, the moving average is one among
an exponentially weighted moving average; or
an extended exponentially weighted moving average.

Other types of moving average can also be used.

According to one or more embodiments, the moving average is determined using a filter. The filter may be an infinite impulse response filter.

According to one or more embodiments, the mean variation is function of a given number of most recent differences, excluding differences above the first threshold.

According to one or more embodiments, the given number of differences further excludes differences below the first threshold, but corresponding to data points within a given time interval following the determination that the output of said integrator being greater than the second threshold.

According to one or more embodiments, the mean variation is determined by obtaining an exponentially weighted moving average of a mean of the given number of differences.

According to one or more embodiments, generating a signal indicative of the detection of an event is performed only if the output of said integrator is greater than a second threshold for a given duration.

According to one or more embodiments, the variable of the system comprises one among a current in the system, a sum of currents in the system, a voltage in the system, a sum of voltages in the system.

According to one or more embodiments, the time series data is representative of the energy of one or more harmonics of at least one among a current or voltage signal in the system.

According to one or more embodiments, the method comprises classifying the anomaly event as one among a normal operations event and an abnormal event; and generating a control signal of the electrical or electromechanical system if the anomaly event is an abnormal event.

Another aspect concerns a device for anomaly event detection in an electrical or electromechanical system, said device comprising a processor and memory, said memory comprising software code, the processor causing the device to perform one of the methods described herein when executing said software code.

Another aspect concerns a computer-readable storage medium comprising code which when executed by a processor of a device causes the device to perform one of the methods described herein.

### BRIEF DESCRIPTION OF DRAWINGS

Non-limiting and non-exhaustive embodiments are described with reference to the following Figures, wherein like reference numerals refer to like parts throughout the various views unless otherwise specified.

FIG. 1 is a schematic diagram of a system overview according to one or more exemplary embodiments.

FIG. 2 is a flow chart of main steps of a method for anomaly event detection according to one or more exemplary embodiments.

FIG. 3 is a block diagram illustrating an exemplary embodiment of a first step of the method of FIG. 2.

FIG. 4 is a block diagram illustrating an exemplary embodiment of a second step of the method of FIG. 2.

FIG. 5 is a flow chart of detailed steps of an exemplary method for anomaly event detection such as the method of FIG. 1.

FIG. 6a is a graph representing time series data points and illustrating the event detection process in a non-limiting manner for the detection of a so-called ‘high-impedance’ fault in a power line.

FIG. 6b is a graph representing an output of an integrator used in the anomaly event detection based on data points shown in FIG. 6b.

FIG. 7 is a block diagram of an anomaly event detection device according to one or more exemplary embodiments.

### DESCRIPTION OF EMBODIMENTS

Various exemplary embodiments will now be described more fully with reference to the accompanying drawings. However, specific structural and functional details disclosed herein are merely representative for purposes of describing the example embodiments. The exemplary embodiments may be embodied in many alternate forms and should not be construed as limited to only the embodiments set forth herein. It should be understood that there is no intent to limit example embodiments to the particular forms disclosed.

It should be appreciated by those skilled in the art that any functions, engines, block diagrams, flow diagrams, state transition diagrams and/or flowcharts herein represent conceptual views of illustrative circuitry embodying the principles of the exemplary embodiments. Functions, actions or steps described herein can be implemented in hardware or software or any combination thereof. If implemented in software, the functions, blocks of the block diagrams and/or flowchart illustrations can be implemented e.g. using software code executed by a processor or a processing device.

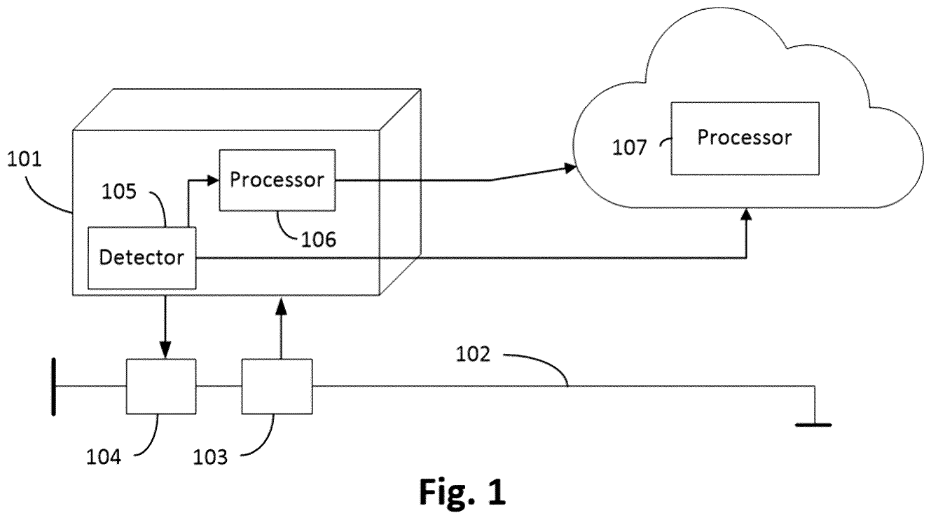

FIG. 1 is a schematic diagram of an exemplary architecture of a system with associated event detection and control functions. The system comprises an event detection device 101. In the frame of the present description, a power grid is used as a non-limiting example of a system for which device 101 provides an event detection service. In FIG. 1, the power grid is represented by power line 102. Sensor 103 provides measurements of at least one time-varying signal representative of the system to be monitored. A control circuit 104 allows device 101 to control the system. For example, control circuit 104 may reduce or cut power on the grid 102 under control of device 101. In the frame of a power grid application, processing device 101 may be an Intelligent Electronic Device (‘IED’), i.e. a processor-based device which controls power grid functions, such as reclosers, circuit breakers, transformers and capacitor banks. Depending on implementation, sensor 103 and control circuit 104 may be integral part of device 101 or separate modules.

Sensor 103 provides time series data of e.g. currents, voltages or energies in the power grid 102. Time series data representative of harmonic components of these representative signals may also be used. If harmonic components are used, these may be determined e.g. through appropriate processing by device 101 of the signals provided by sensor 103. According to one embodiment, the time series data representative of harmonic components is the energy magnitude of either the 3^{rd} or the 5^{th} harmonic, or the sum of both.

Device 101 carries out an event detector function 105 and an event processor function 106. Event detector 105 and event processor 106 are shown in FIG. 1 as distinct boxes for illustrative purposes only—in an actual implementation, the functions may be carried out by the same or overlapping or disjoint hardware, as needed.

An event detected by event detector 105 may be processed either by processor 106 for feature extraction and fault classification or sent to a server or cloud processing platform 107 for that purpose. The latter solution allows to reduce the complexity of device 101. As a function of fault classification results determined by device 101 itself or based on return information from a remote device, device 101 applies appropriate control measures to power grid 102 through control circuit 104.

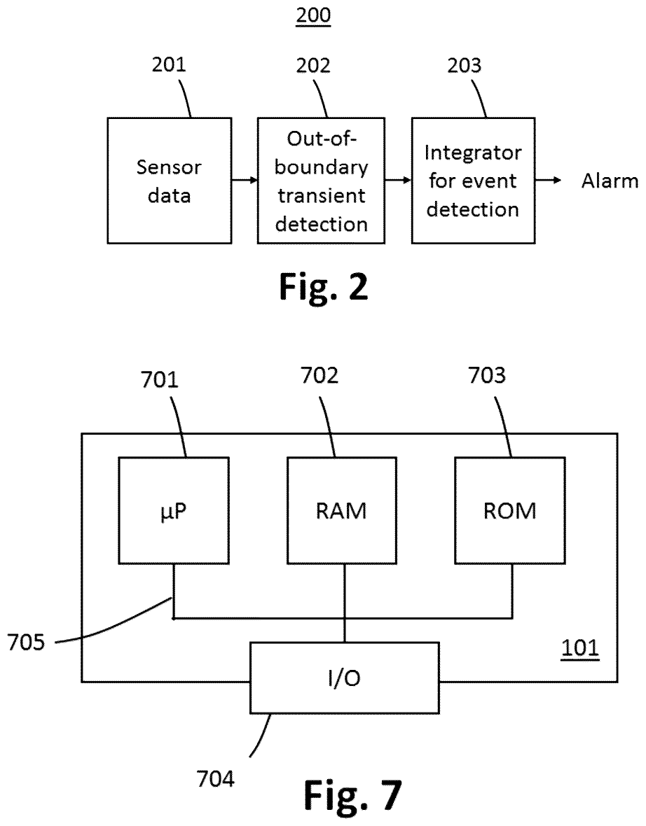

FIG. 2 is a flowchart of a method 200 for event detection according to one or more embodiments. The method comprises acquiring sensor data (at 201), out-of-boundary transient detection (at 202) and integrator-based event detection (at 203).

According to one embodiment, the out-of-boundary transient detection comprises the determination of the residual error between the acquired sensor data (or a representative derivative thereof, such as harmonic component data) and a baseline reference based on the acquired sensor data with regard to a threshold. It also comprises an estimation of the threshold. The baseline reference is calculated by determining a moving average of the acquired sensor data, i.e. an average over a number of data samples within a time window.

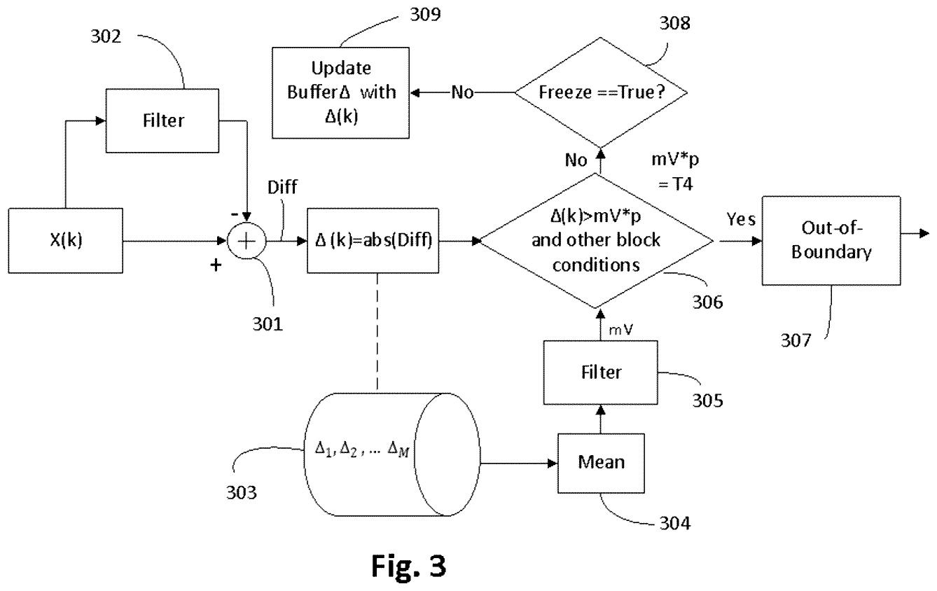

FIG. 3 is a diagram detailing the out-of-boundary transient detection of FIG. 2 according to one embodiment.

The residual error at a step k is obtained by subtracting (at 301) the baseline reference at step k from the acquired sensor data X(k) at step k. According to the process of FIG. 3, the baseline reference is calculated by applying a filter 302. Filter 302 can for example be an infinite impulse response (IIR) filter. Other filters may be used. The equation for an extended IIR filter can be as follows:

$$X \text{?} = X {\text{?}}_{k - 1} - X {\text{?}}_{k - 1} ) * min ( 1 , \text{?} + ( \text{?} - \text{?} ) \cdot ( 1 - Pt ) ) \qquad Eq . 1$$

$$\text{?} \text{indicates text missing or illegible when filed}$$

In equation 1, Xₖ represents the baseline reference at step k, and k is an integer equal or greater than one. Δt is the time step. rₘᵢₙ and rₘₐₓ are the minimum and maximum time constants for Xₖ. Pt is similar to a probability density function of Xₖ evaluated under distribution equation (3) which varies in a range of [0, 1]:

$$P t = exp ( \text{?} ( \text{?} ) ) \qquad Eq . 2$$

$$\text{?} \text{indicates text missing or illegible when filed}$$

In equation 2, aₖ₋₁ is the estimated standard deviation at step k−1. When rₘₐₓ=rₘᵢₙ, the modified exponential weighted average (EWA) will be the same as traditional EWA. It is to be noted that the notation X(k) and Xₖ are equivalent. The resulting residual error Δ(k) is:

$$L 1 ( k ) = abs ( {X}_{k} - X {\text{?}}_{k} ) \qquad Eq . 3$$

$$\text{?} \text{indicates text missing or illegible when filed}$$

The time constant of filter 302 dynamically changes in the range of [rₘᵢₙ, rₘₐₓ] depending on whether the current value of Xₖ is within the normal range or not.

According to a variant embodiment, the equation for an IIR filter can be as follows:

$$X {\text{?}}_{k} = X {\text{?}}_{k - 1} + ( {X}_{k} - X {\text{?}}_{k - 1} ) * ( 1 , \text{?} ) \qquad Eq . 1 ’$$

$$\text{?} \text{indicates text missing or illegible when filed}$$

The value of rₘₑₐₙ represents the time constant of filter 302, which functions as an exponentially weighted moving average. As illustrative and non-limiting example, rₘₑₐₙ can be of the scale of few seconds.

A threshold, or margin, is estimated to determine which values of Xₖ lie outside of the boundary compared to the baseline reference. The threshold is estimated as a function of an average of residual errors at previous steps.

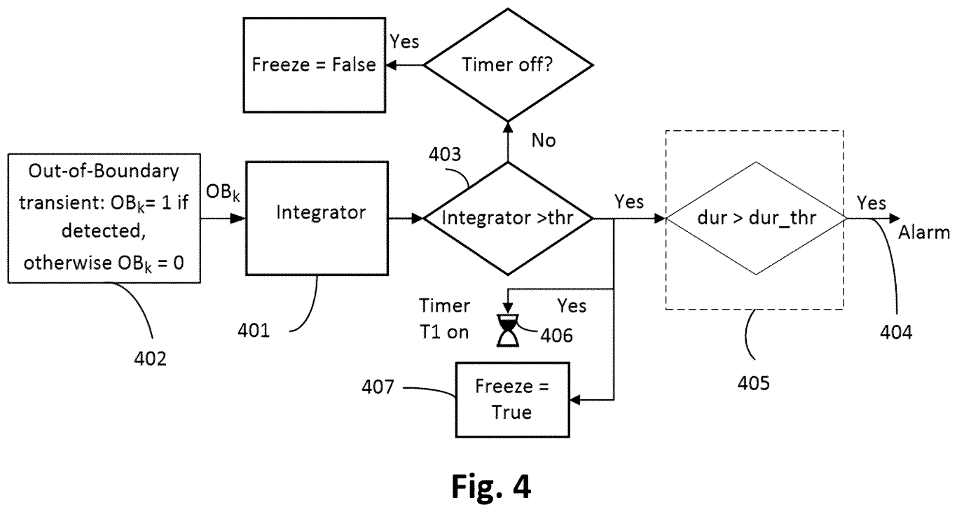

According to the present embodiment, residual errors which are potentially abnormal are discarded. Discarded residual errors are those which correspond to an out-of-boundary transient or which occur during a duration T1 following detection of an event. T1 will be described in more detail later in conjunction with FIG. 4. Its function is to keep the threshold estimation unchanged when oscillations following an event occur, with the signal traversing the entire in-boundary zone during such an oscillation and thus producing invalid in-boundary values which should be excluded from the average calculation.

In the diagram of FIG. 3, the M residual error values Δ1, Δ2, . . . . ΔM, taken into account for the threshold estimation are stored in a buffer 303. According to one embodiment, a flag called ‘freeze’ is introduced which, when true, does not allow a residual value to be added to the buffer. The mean variation, mV, of the residual values is determined. In FIG. 3, this is shown at 304 (mean calculation) and 305 (variation calculation). The choice of M determines how sensitive to residual error variations the current signal Xₖ value is.

Block 305 can for example be implemented using a filter similar to filter 302, i.e. an IIR filter:

$$m V ( k + 1 ) = m V ( k ) + ( mean ( abs ( {Δ}_{1} ) , abs ( {Δ}_{2} ) … abs ( {Δ}_{M} ) ) - m V ( k ) * min ( 1 , \text{?} ) \qquad Eq . 3$$

$$\text{?} \text{indicates text missing or illegible when filed}$$

The threshold (i.e. margin) is obtained by multiplying the mean variation mV by a coefficient p, also called boundary parameter. p depends on the context of an actual implementation. In a normal distribution, when p=2, it proximately equals to twice the standard deviance which corresponds to 95% of the confidence interval. For noisier systems, p could be larger. When the absolute value of a residual error is greater than the threshold (test at 306) and other block conditions met, the corresponding data value is identified as an out-of-boundary transient and feed the integrator of process 203. The value rᵥₐᵣ for filter 305 is selected much larger than the rₘᵢₙ and rₘₐₓ for filter 302, considering that the threshold usually varies slowly over time. As illustrative and non-limiting examples, Ivar could be equal to a few seconds or minutes whereas rₘᵢₙ and rₘₐₓ can be of the scale of few seconds. Optionally, the other block conditions in 306 can be defined based upon the needs of different applications. For instance, in a powerline system, the percentage of changes for an anomaly event needs to be higher than a certain value. Or it could be that the mean variation mV has to be larger than the system noise level if it is available. At 307, an appropriate output of process 202 is generated based on the output of the threshold comparison at 306 to feed process 203.

FIG. 4 is a diagram detailing the integrator-based event detection process 203 of FIG. 2 according to one embodiment. The process uses a leaky integrator which accumulates out-of-boundary transients detected by process 202, but also leaks over time. According to one embodiment, the behavior of integrator 401 can be described as follows:

$$If {OB}_{k} \geq {I}_{\overline{k} - 1} then$$

$${\overline{I}}_{k} = {\overline{I}}_{k - 1} + ( {OB}_{k} - {\overline{I}}_{k - 1} ) * min ( 1 , \text{?} )$$

$$else$$

$${\overline{I}}_{k} = {\overline{I}}_{k - 1} + ( {OB}_{k} - {\overline{I}}_{k - 1} ) * min ( 1 , \text{?} )$$

$$\text{?} \text{indicates text missing or illegible when filed}$$

where OBₖ represents the output of the out-of-boundary transient detection process 202 for the current signal value at step k, current transient, Īₖ is the integrator output at step k, Δt is the time step, tau_upper is a first time constant applied when an out-of-boundary transient is detected, tau_lower is a second time constant applied when no out-of-boundary transient is detected. tau_upper defines how fast the integrator accumulates out-of-boundary transients, whereas tau_lower defines how fast the integrator leaks.

According to the present non-limiting embodiment, OBₖ is defined (at 402) as follows: if an out-of-boundary transient is detected at step k, then OBₖ=1, else OBₖ=0. Since the input to the integrator is either 0 or 1, the output signal of the integrator will be in the range [0, 1].

At 403, the output Īₖ of the integrator is compared to a threshold ‘thr’. If Īₖ is greater than thr, an event is detected and a corresponding alarm signal is generated (at 404).

A mechanism is furthermore implemented to reduce or eliminate the impact of signal values following event detection on the calculation of the threshold mV*p used to determine whether a value is an out-of-boundary transient or not. Indeed, given relatively large oscillations during or following an event, signal values may lie within the margin defined by the threshold mV*p around the baseline reference, but such signal values may modify the margin calculation in an unpredictable manner. In the frame of the present embodiment, such signal values are blocked from contributing to the margin calculation (i.e. the corresponding residual error is not stored in buffer 303) during a time period following the detection of an event. This can, for example, be performed using a countdown timer T1 and a flag (‘Freeze’), as already mentioned in conjunction with the description of process 202 and FIG. 3. When the integrator output is greater than threshold thr, countdown timer T1 is triggered (406) to start counting down and the Freeze flag is set to ‘true’ (407). When the integrator output is lower than threshold thr, i.e. no event is detected, a check is carried out whether the timer T1 is on (still counting down) or off (countdown is over, or timer was not triggered). If the timer is off, then the flag is set to ‘false’. While the flag is True, residual errors-whether corresponding or not to out-of-boundary transients—are not stored in buffer 303 and hence do not contribute to the determination of mean variation mV and consequently to threshold mV*p. Timer T1 duration is function of a specific application, e.g. function of the duration of an event and its oscillations.

According to a variant embodiment shown in a dashed rectangle at 405 in FIG. 4, the detection of an event is function of the duration ‘dur’ during which the output of the integrator is greater than threshold thr. This duration is compared to duration threshold ‘dur_thr’. An event is detected only when the output of the integrator is greater than threshold thr for a duration longer than threshold dur_thr.

Thresholds thr, and dur_thr if implemented, are chosen as a function of a specific application.

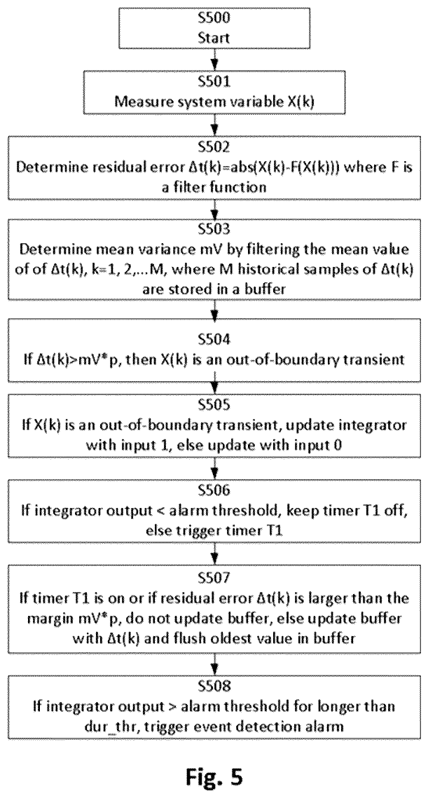

FIG. 5 is a flowchart of an event detection method according to one or more non-limiting embodiments. The process comprises:
S500: Start event detection process.
S501: Measure system variable X(k), for example using a sensor such as sensor 103 or an edge device. According to variant embodiments, the sensor signal or signals are further processed to obtain the input data, e.g. harmonic energy.
S502: Determine residual error Δt(k)=abs(X(k)−F(X(k))) where F is a filter function, e.g. based on equation 1.
S503: Determine mean variance mV by filtering the mean value of Δt(k), k=1, 2, . . . . M, where M historical samples of Δt(k) are stored in a buffer.
S504: If (Δt(k)>mV*p, then X(k) is an out-of-boundary transient.
S505: If X(k) is an out-of-boundary transient, update integrator with input 1, else update with input 0.
S506: If integrator output<alarm threshold, keep timer T1 off, else trigger timer T1.
S507: If timer T1 is on or if residual error Δt(k) is larger than the margin mV*p, do not update buffer, else update buffer with Δt(k) and flush oldest value in buffer if the buffer is full.
S508: If integrator output>alarm threshold for longer than dur_thr, trigger event detection alarm.

An exemplary application of the above process will now be described. The application concerns the detection of a ‘High Impedance Fault’ (‘HiZ’). HiZ detection has long been a challenge in maintaining the reliability of power distribution systems. HiZ faults typically occur when a downed powerline conductor falls on a high impedance surface, such as grass, sand, asphalt or gravel, or when a tree limb falls on the conductor. When such a fault happens, the conductor still carries current, which often lies within the normal functioning range. This prevents detection e.g. with a traditional overcurrent relay. Identifying such faults in a timely manner and taking the necessary actions to correct them is crucial in order to eliminate the dangerous situation generated by the fault. Since a HiZ fault is usually associated with bursts of harmonic energy, the primary feature or input to the event detection device, X(k), is typically data representative of change in the harmonic contents of single phase or ground currents, e.g. the 3^{rd} and the 5^{th} harmonics. X(k) is the residual between the harmonic contents of the recorded current signal and its baseline.

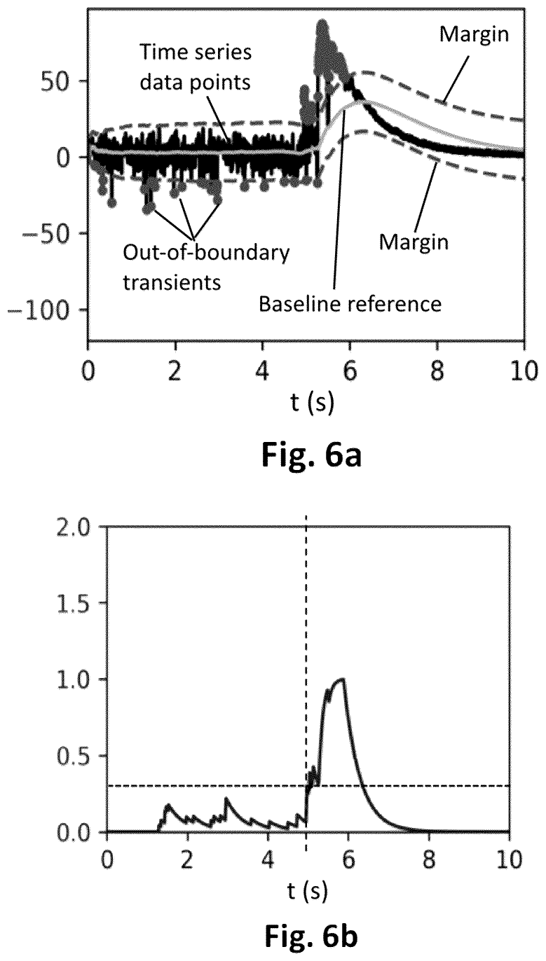

FIG. 6a and FIG. 6b are graphs illustrating the detection of an anomaly event corresponding to a high impedance fault in a power line system, applying the processes disclosed herein. In the case of FIGS. 6a and 6b, the HiZ fault occurs at 5s. FIG. 6a is a graph showing the change in harmonic power (DB) over time (X(k)) for an exemplary HiZ fault, the associated baseline reference (light grey line) and the estimated margin around the baseline reference (two dashed lines). Data points considered as out-of-boundary transients, i.e. lying beyond the margin, are identified by fatter dots. FIG. 6b is a graph showing the output of the integrator, with an event detection threshold of 0.3, identified by a horizontal dashed line. A vertical dashed line identifies the moment when the integrator output crosses the event detection threshold. In FIG. 6, the time series data points representative of the change in harmonic energy oscillate around the baseline reference until the HiZ fault appears. It is to be noted that although the data points cross the estimated margin before the HiZ event, which leads to out-of-boundary transients being detected, this does not result in the integrator providing an output greater than the event detection threshold. This is obtained through the leaking of the integrator. Only when the out-of-boundary transients occur substantially continuously due to the HiZ fault does the integrator output reach the event detection threshold and triggers the event alarm. The time series data points following the event detection can be recorded and stored for further feature extraction, HiZ fault classification and appropriate action.

FIG. 7 is a schematic diagram of an event detection device 101. Device 101 comprises a processor or microcontroller 701, a working memory 702, a long term memory 703 and a collection of interfaces 704. Blocks 701 to 704 are connected through bus 705. The long term memory 703 holds software code. The interfaces 704 comprise the interfaces with bus 705, sensor 103 and control circuit 104. When the processor 701 executes the software code, it causes the device 101 to carry out one or more of the methods described herein. For example, processor 701 may execute software code causing device 101 to carry out out-of-boundary data detection and processing. Device 101 may comprise additional functional blocks, such as a user interface, a display . . . .

The proposed method and device enable monitoring a baseline reference and noise variance of the system, and identification of abnormal changes. The processing can be performed in real time on high-rate data. The method can easily be implemented in a device able to perform simple data processing, such as an IED. Only the data corresponding to detected events need be stored and processed for further analysis in real time. Complexity and cost is thus maintained at a reasonable level.

The use of a fixed threshold or margin to detect out-of-boundary transients in the data points can lead to the selection of a relatively high value to avoid false alarms. This can however result in a failure to detect subtle changes. The embodiments disclosed herein implement an adaptive threshold a.k.a margin combined with a leaky integrator used as an over-threshold event counter. This allows limiting false alarms while still enabling detection of subtle changes that persist over a relatively long time.

One advantage of utilizing a leaky integrator instead of a traditional counter is its ability to perform a weighted sum. Unlike simple counters, which disregard the timing pattern of the items being counted, a leaky integrator gives more weight to recent events compared to those that occurred in the distant past. In addition, the integrator leaks over time. Sparse events are thus not counted. This feature can help avoid that noise triggers a false alarm.

Methods that use low pass filters to smooth filters may be used to reduce false alarms and detect subtle changes. However, these methods limit the high frequency characteristics of the signals and may thus fail to detect events associated with high frequency changes. The embodiments described herein do not rely on low pass filtering.

One or more embodiments concern a device for anomaly event detection in an electrical or electromechanical system (102), said device comprising:
means (704) for acquiring time series data points representative of a variable of the system;
means (701) for determining whether a difference (Δ(k)) between a data point (X(k)) and a moving average of data points is greater than a first threshold, wherein the first threshold is function of a mean of said difference; and as a result of the determination, for providing (S505) an input to a leaky integrator (401) configured to count data points for which the difference is greater than the first threshold; and for determining (S508) whether an output of said integrator is greater than a second threshold and in the affirmative, generating (404, S508) a signal indicative of the detection of an anomaly event.

1. A method for anomaly event detection in an electrical or electromechanical system, said method being carried out by a device comprising a processor, said method comprising:
acquiring time series data points representative of a variable of the system;
determining whether a difference (Δ(k)) between a data point (X(k)) and a moving average of data points is greater than a first
threshold, wherein the first threshold is function of a mean of said difference;
as a result of the determination, providing an input to a leaky integrator configured to count data points for which the difference is greater than the first threshold;
determining whether an output of said integrator is greater than a second threshold and in the affirmative, generating a signal indicative of the detection of an anomaly event.

2. The method according to claim 1, wherein the time series data representative of a variable of the system comprises one among one or more measured currents, voltages or powers, or a variable representative of harmonics of one or more measured currents, voltages or powers.

3. The Method according to claim 1, wherein said moving average is one among an extended exponentially weighted moving average or an exponentially weighted moving average.

4. The method according to one of the preceding claims, wherein said moving average is determined using a filter.

5. The method according to claim 4, wherein the filter is an infinite impulse response filter.

6. The method according to claim 1, wherein the mean variation (mV) is function of a given number of most recent differences, excluding differences above the first threshold.

7. The method according to claim 6, wherein the given number of differences further excludes differences below the first threshold, but corresponding to data points within a given time interval (T1) following the determination that the output of said integrator being greater than the second threshold.

8. The method according to claim 6, wherein the mean variation (mV) is determined by obtaining an exponentially weighted moving average of a mean of the given number of said differences.

9. The method according to claim 1, wherein generating a signal indicative of the detection of an event is performed only if the output of said integrator is greater than a second threshold for a given duration.

10. The method according to claim 1, comprising: classifying the anomaly event as one among a normal operations event and an abnormal event; and generating a control signal of the electrical or electromechanical system if the anomaly event is an abnormal event.

11. The device for anomaly event detection in an electrical or electromechanical system, said device comprising a processor and memory, said memory comprising software code, the processor causing the device to perform one of the methods according to claim 1 when executing said software code.

12. The computer-readable storage medium comprising code which when executed by a processor of a device causes the device to perform the method according to claim 1.
